(19) United States
(12) Patent Application Publication
(10) Pub. No.: US 2026/0068200 A1
(43) Pub. Date: Mar. 5, 2026

(54) BIPOLAR JUNCTION TRANSISTOR WITH FINFET STRUCTURE

(71) Applicant: Taiwan Semiconductor Manufacturing Company, LTD., Hsinchu (TW)

(72) Inventors: Yu-Hsuan Chang, Hsinchu (TW); Chun-Ting Chen, Hsinchu (TW); Chih-Pin Hung, Hsinchu (TW); Chin-Hsun Pan, Kaohsiung (TW); Chung-Hao Chu, Hsinchu (TW); Fu-Yang Chu, Hsinchu (TW)

(21) Appl. No.: 18/819,114

(22) Filed: Aug. 29, 2024

(51) Int. Cl. H01L 29/732; H01L 21/265; H01L 29/08; H01L 29/10; H01L 29/417; H01L 29/66

(52) U.S. Cl. CPC H10D 10/441; H10D 10/058; H10D 62/135; H10D 62/138; H10D 62/177; H10D 64/231

(57) ABSTRACT

In a method of forming a bipolar junction transistor (BJT) structure, an emitter/base/collector structure is formed, comprising mutually parallel fins with an insulator material disposed between the fins. Each fin of the emitter/base/collector structure has first and second peripheral regions doped with a first doping type on opposite sides of a central region doped with a second doping type opposite the first doping type. The first peripheral regions of the fins are an emitter of the BJT structure, the central regions of the fins are a base of the BJT structure, and the second peripheral regions of the fins are a collector of the BJT structure. Continuous emitter, base, and collector contact strips are epitaxially deposited on the emitter, base, and collector of the BJT structure, respectively.

### BACKGROUND

The following relates to semiconductor bipolar junction transistor devices and methods of forming same, and their application to electronic devices including transistor circuits, computers, cell phones, controllers, signal amplifiers, mixed-signal integrated circuits, switching circuits and others.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A illustrates a PNP bipolar junction transistor (PNP BJT) structure according to an example embodiment of the present disclosure (Embodiment 1A), and

FIG. 1B illustrates a NPN bipolar junction transistor (NPN BJT) structure according to another example embodiment of the present disclosure (Embodiment 1B).

FIG. 2A is a cross sectional view of the PNP BJT structure of FIG. 1A according to an example embodiment of the present disclosure (Embodiment 1A), and

FIG. 2B is a cross sectional view of the NPN BJT structure of FIG. 1B according to an example embodiment of the present disclosure (Embodiment 1B).

FIG. 3 is another perspective view of the PNP BJT structure according to an example embodiment of the present disclosure (Embodiment 1A), FIG. 3 illustrating various dimensional details of the PNP BJT structure.

FIG. 4A is a perspective view of the PNP BJT structure of FIG. 1A including dummy fins according to an example embodiment of the present disclosure (Embodiment 1A/2A), and FIG. 4B is a cross sectional detail view of FIG. 4A.

FIG. 5A is a perspective view of the NPN BJT structure of FIG. 1B including dummy fins according to another example embodiment of the present disclosure (Embodiment 1B/2B) and FIG. 5B is a cross sectional detail view of FIG. A.

FIG. 6A illustrates a PNP BJT structure which includes multiple BJTs according to an example embodiment of the present disclosure (Embodiment 3A), and FIG. 6B illustrates an equivalent circuit of the PNP BJT structure of FIG. 6A.

FIG. 7A illustrates a NPN BJT structure which includes multiple BJTs according to another example embodiment of the present disclosure (Embodiment 3B) and FIG. 7B illustrates an equivalent circuit of the NPN BJT structure of FIG. 7A.

FIG. 8 illustrates various process steps of forming a BJT structure according to example embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The term “layer”, as used herein, may include a single layers or multiple layers.

Bipolar junction transistors (BJTs) are used in a wide range of analog, digital, and mixed analog/digital integrated circuits. BJTs can be grouped as NPN BJTs (NBJTs) and PNP BJTs (PBJTs). An NPN BJT is an NPN transistor comprising doped regions, namely an n-type emitter E, a p-type base B, and an n-type collector C. Conversely, a PNP BJT is a PNP transistor with a p-type emitter E, an n-type base B, and a p-type collector. To enhance emitter injection efficiency, in some designs the emitter E is encircled by the base B and collector C. The traditional BJT layout is a vertical design. Vertical BJTs employ a vertical structure, for example formed by double-diffusion. This type of transistor is sometimes known as a substrate transistor.

Field-effect transistors (FETs) are used in integrated circuits and can include a fin structure (FINFET) to improve gate control of the FET channel by increasing the contact area between the gate and the channel.

BJTs and FINFETs have different structures and are typically fabricated using different fabrication processes.

Provided herein are BJT structures that may be fabricated using fabrication processes compatible with fin type FET fabrication. These are sometimes referred to herein as fin type BJT structures. Advantages of the fin type BJT structures include potentially higher serial aerial density of the BJTs relative to traditional BJT structures, higher Beta (gain) achieved by a narrower gate length associated with the fin BJT base widths formed within the BJT fins, and a scalable base width W_{B}. In traditional BJT structures, the use of well implant structure results in a thicker base width (WB), which leads to lower Beta. In addition, contact processes have more defects and process variations, resulting in worse mismatches.

One of the challenges involves the formation of contacts to BJTs. For example, it is difficult to contact the base region of a BJT, without additional masking and/or process steps, without significant areal penalty, and without an increase in mismatch of the BJTs. A further advantage of the disclosed fin type BJT devices is improved compatibility with CMOS workflows that include FINFET fabrication.

Further features/advantages/benefits of this disclosure and the embodiments described herein, include, but are not limited to, providing a continuous layer of contact, i.e. contact strip, a first continuous layer of contact material electrically connecting multiple emitter regions, a second continuous layer of contact material electrically connecting multiple base regions, and a third continuous layer of contact material electrically connecting multiple collector regions. Using a continuous contact layer, as compared to discrete contacts for each emitter, base and collector regions, provides a lower mismatch of the resulting fin type BJTs.

Still further features/advantages/benefits of this disclosure and the embodiments described herein, include, but are not limited to, forming the continuous layer of contacts, i.e. contact strips, after removal of an upper portion the insulator material between BJT fins, whereby only the fin separation insulator material is removed, by for example etching, without any removal of the BJT fin material prior to forming the continuous layer contacts, thereby reducing contact defects and process variations. In comparison, a noncontinuous contact layer process includes etching an STI and fin first, followed by growing the BJT contacts, which leads to relatively more defects.

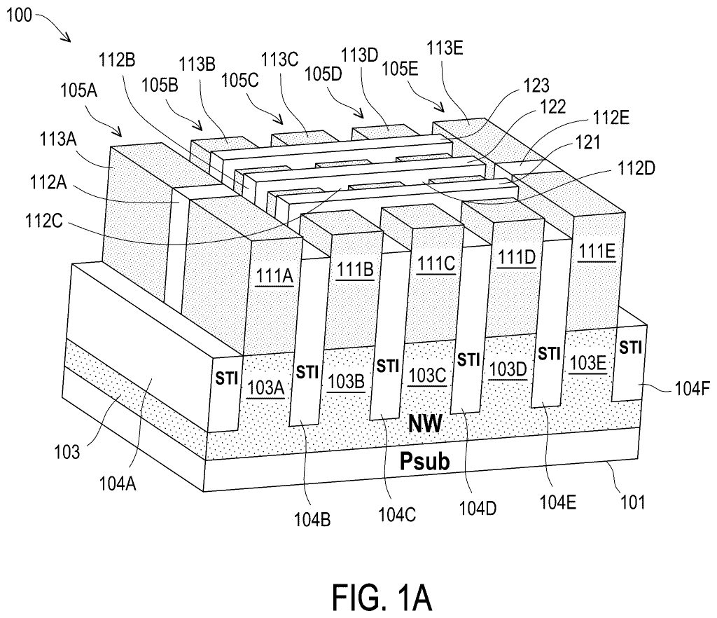

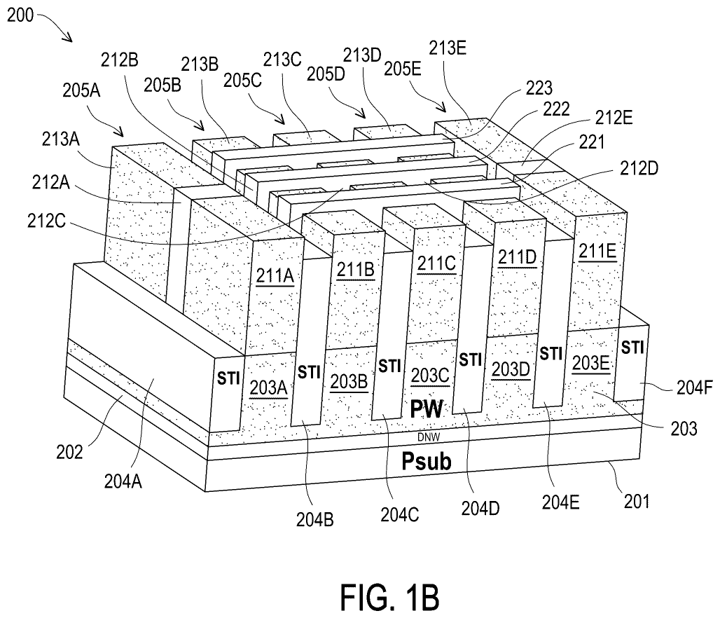

With reference to FIG. 1A, illustrated is a fin type PNP bipolar junction transistor (PNP BJT) structure 100 according to an example embodiment of the present disclosure (Embodiment 1A). As will be further described below, the fin type PNP BJT structure described is also applicable to NPN BJT structures with suitable changes in doping operations.

As shown, the fin type PNP BJT structure 100 includes a P-type semiconductor substrate 101, an N-type well (NW) 103 formed on the P-type semiconductor substrate 101 to create an isolation region, optionally including multiple fingers or buried NW fins 103A-103E, which isolates PNP BJT fins 105A-105E from the substrate 101. Example materials of the substrate 101 include Silicon (Si), Germanium (Ge) Gallium Arsenide (GaAs), or another semiconductor material. The illustrative examples employ a silicon substrate 101. As shown, each of the NW fingers 103A-103E and PNP BJT fins 105A-105E are isolated from each other with isolation regions 104A-104F, which can be formed with shallow trench isolation (STI) fabrication processes, and the like, such as local oxidation of silicon to form silicon dioxide area (LOCOS) fabrication processes and deep trench isolation (DTI) fabrication processes.

Each of the PNP BJT fins 105A-105E is doped to form a P doped emitter region (111A-111E, respectively), a N doped base region (112A-112E, respectively), and a P doped collector region (113A-113E, respectively). The doping can suitably employ ion implantation. Example P type implant dopants include Boron (B), Boron Fluoride (BF2), In and Carbon (C), with a constant and/or gradient doping profile. Example N type implant dopants include N, P, As, Sb and C. The doping concentrations in some embodiments include an Emitter dopant concentration>Base dopant concentration>Collector dopant concentration.

In other words, provided and shown in FIG. 1A is a fin type PNP BJT structure including mutually parallel fins 105A-105E with an insulator material 104A-104E disposed between the fins 105A-105E, the mutually parallel fins 105A-105E having regions of alternating first and second doping types along the fins, the regions including at least one emitter region of the first doping type, at least one base region of the second doping type, and at least one collector region of the first doping type.

Emitter continuous contact strip 121 covers an exposed or top emitter region of each of the PNP BJT fins 105A-105E to electrically connect emitter regions 111B, 111C and 111D. As will be further described below, according to an example embodiment described herein, outer or edge emitter regions 111A and 111E are configured as dummy emitter regions of dummy fins 105A and 105E, respectively, and are not electrically connected by the emitter continuous contact strip 121 to the inner or middle BJT emitter regions 111B, 111C and 111D of the fin type PNP BJT structure. Because of possible fabrication process variations and stability associated with the outer edge fins 105A and 105E, the dummy fins 105A and 105E are advantageously excluded from the being electrically connected to the inner BJT finger emitter regions 111B, 111C and 111D, thereby reducing BJT mismatch.

According to an example embodiment, the emitter contact strip 121 is epitaxially deposited on the emitter region of the BJT structure. Example contact materials include, but are not limited to, epitaxial silicon, epitaxial Silicon Germanium (SiGe) or epitaxial gallium phosphide (GaP). According to an example embodiment, before the epitaxial depositing, an upper portion of the insulator material 104B, 104C and 104D is removed from between the fins, for example by etching, without etching or removal of any of the upper portions of the fin emitter regions 111B, 111C and 111D, thereby reducing contact defects and process variations.

Similar to the emitter continuous contact strip 121, base continuous contact strip 122 covers an exposed or top base region of each of the PNP BJT fins 105A-105E to electrically connect base regions 112B, 112C and 112D. As will be further described below, according to an example embodiment described herein, outer or edge base regions 112A and 112E are configured as dummy emitter regions of dummy fins 105A and 105E, respectively, and are not electrically connected by the base continuous contact strip 122 to the inner or middle BJT base regions 112B, 112C and 112D of the fin type PNP BJT structure. Because of possible fabrication process variations and stability associated with the outer edge BJT fins 105A and 105E, the dummy fins 105A and 105E are excluded from the being electrically connected to the inner BJT finger base regions 112B, 112C and 112D, thereby reducing BJT mismatch.

According to an example embodiment, the base contact strip 122 is epitaxially deposited on the base region of the BJT structure. According to another example embodiment, before the epitaxial depositing, an upper portion of the insulator material 104B, 104C and 104D is removed from between the fins, for example by etching, without any etching or removal of any of the upper portions of the fin base regions 112B, 112C and 112D, thereby reducing contact defects and process variations.

Similar to the emitter continuous contact strip 121 and base contract strip 122, collector continuous contact strip 123 covers an exposed or top collector region of each of the PNP BJT fins 105A-105E to electrically connect collector regions 113B, 113C and 113D. As will be further described below, according to an example embodiment described herein, outer or edge collector regions 113A and 113E are configured as dummy emitter regions of dummy fins 105A and 105E, respectively, and are not electrically connected by the collector continuous contact strip 123 to the inner or middle BJT collector regions 113B, 113C and 113D of the fin type PNP BJT structure. Because of possible fabrication process variations and stability associated with the outer edge BJT fins 105A and 105E, the dummy fins 105A and 105E are excluded from the being electrically connected to the inner BJT finger collector regions 113B, 113C and 113D, thereby reducing BJT mismatch. According to an example embodiment, the collector contact strip 123 is epitaxially deposited on the collector region of the BJT structure. According to another example embodiment, before the epitaxial depositing, an upper portion of the insulator material 104B, 104C and 104D is removed from between the fins, for example by etching, without any etching or removal of any of the upper portions of the fin collector regions 113B, 113C and 113D, thereby reducing contact defects and process variations.

As described above, the emitter/base/collector contact strips 121/122/123 are epitaxially deposit ed on the respective emitter/base/collector region of the BJT structure. Before the epitaxial depositing, an upper portion of the insulator material 104 is optionally removed from between the fins, for example by etching, without any etching or removal of any of the upper portions of the fin emitter/base/collector regions 111A-111E/112A-112E/113A-113E. This provides a large contact area (around the top and upper sidewalls of the fins), thereby reducing contact defects and process variations.

According to an example embodiment, the emitter contact is deposited as a continuous emitter contact strip 121 disposed over all of the emitter regions 111B-111D of the mutually parallel fins 105B-105D of the emitter/base/collector structure; the base contact is deposited as a continuous base contact strip 122 disposed over all of the base regions 112B-112D of the mutually parallel fins 105B-105D of the emitter/base/collector structure; and the collector contact is deposited as a continuous collector contact strip 123 disposed over all of the collector regions 123B-123D of the mutually parallel fins of the emitter/base/collector structure. Further, according to an example embodiment, the continuous emitter contact strip 121, the continuous base contact strip 122, and the continuous collector contact strip 122 are mutually parallel; and the continuous emitter contact strip 121 is perpendicular to the fins 105A-105E of the emitter/base/collector structure; the continuous base contact strip 122 is perpendicular to the fins 105A-105E of the emitter/base/collector structure; and the continuous collector contact strip 123 is perpendicular to the fins 105A-105E of the emitter/base/collector structure.

In some embodiments, the BJT 100 may be part of an integrated circuit (IC) that also includes FINFETs. In such an embodiment, there is advantageously a high degree of compatibility and overlap between fabrication of the FINFETs and the BJTs 100 of the IC, due to the BJT 100 having a FINFET architecture (i.e., being formed utilizing a set of fins/dummy fins 105A-105E analogous to fins of a FINFET). The fins of the fin type BJT 100 can be formed by the fabrication operations that form the fins of the FINFETs, with suitable modification of the FINFET fabrication photolithography masks to additionally delineate the fins of the BJT 100. Additional doping implantation operations may be added to the FINFET workflow to provide doping of the emitter, base, and collector regions of the BJT 100. The deposition of the emitter, base, and collector continuous contact strips 121, 122, 123 of the BJT 100 may be performed concurrently with epitaxial deposition of the source, gate, and/or collector contacts of the FINFETs, again with suitable modification of the photomasks. Alternatively, if doping of the continuous contact strips 121, 122, 123 is different than that of the FINFET contacts, then additional epitaxy steps may be included to form the continuous contact strips 121, 122, 123 of the BJT 100, which is a minor addition to the FINFET workflow.

The fin structure described above includes a gate length (Lg) process of fabrication, where the resulting base width of the BJT is utilized as a gate length of the device. Since the Lg process can achieve smaller dimensions, this method can result in a narrow base width, which increases the Beta of the PNP BJT structure. Furthermore, the base width can be modulated by different gate length masks according to different circuit application requirements.

With reference to FIG. 1B, illustrated is a fin type NPN bipolar junction transistor (NPN BJT) structure 200 according to another example embodiment of the present disclosure (Embodiment 1B).

As shown, the fin type NPN BJT structure 200 includes a P-type semiconductor substrate 201, and a deep N-type well (DNW) 202 and P-type well (PW) 203 formed on the P-type semiconductor substrate 201 to create an isolation region, optionally including multiple fingers or buried PW fins 203A-203E, which isolates NPN BJT fins 205A-205E from the substrate 201. Example materials of the substrate 201 include Silicon (Si), Germanium (Ge) Gallium Arsenide (GaAs), or another semiconductor material. The illustrative examples employ a silicon substrate 201. As shown, each of the PW fingers 203A-203E and NPN BJT fins 205A-205E are isolated from each other with isolation regions 204A-204F, which can be formed with known shallow trench isolation (STI) fabrication processes, and the like, such as local oxidation of silicon to form silicon dioxide area (LOCOS) fabrication processes and deep trench isolation (DTI) fabrication processes.

Each of the NPN BJT fins 205A-205E is doped to include a N doped emitter region (211A-211E, respectively), a P doped base region (212A-212E, respectively), and a N doped collector region (213A-213E, respectively). The doping can suitably employ ion implantation. Example P type implant dopants include Boron (B), Boron Fluoride (BF₂), In and Carbon (C), with a constant and/or gradient doping profile. Example N type implant dopants include N, P, As, Sb and C. The doping concentrations in some embodiments include an Emitter dopant concentration>Base dopant concentration>Collector dopant concentration.

In other words, provided and shown in FIG. 1B is a fin type NPN BJT structure including mutually parallel fins 205A-205E with an insulator material 204A-204E disposed between the fins 205A-205E, the mutually parallel fins 205A-205E having regions of alternating first and second doping types along the fins, the regions including at least one emitter region of the first doping type, at least one base region of the second doping type, and at least one collector region of the first doping type.

Emitter continuous contact strip 221 covers an exposed or top emitter region of each of the NPN BJT fins 205A-205E to electrically connect emitter regions 211B, 211C and 211D. As will be further described below, according to an example embodiment described herein, outer or edge emitter regions 211A and 211E are configured as dummy emitter regions of dummy fins 205A and 205E, respectively, and are not electrically connected by the emitter continuous contact strip 221 to the inner or middle BJT emitter regions 211B, 211C and 211D of the fin type NPN BJT structure. Because of possible fabrication process variations and stability associated with the outer edge fins 205A and 205E, the dummy fins 205A and 205E are advantageously excluded from the being electrically connected to the inner BJT finger emitter regions 211B, 211C and 211D, thereby reducing BJT mismatch.

According to an example embodiment, the emitter contact strip 221 is epitaxially deposit ed on the emitter region of the BJT structure. Example contact materials include, but are not limited to, epitaxial silicon, epitaxial Silicon Germanium (SiGe) or epitaxial gallium phosphide(GaP). According to an example embodiment, before the epitaxial depositing, an upper portion of the insulator material 204B, 204C and 204D is removed from between the fins, for example by etching, without etching or removal of any of the upper portions of the fin emitter regions 211B, 211C and 211D, thereby reducing contact defects and process variations.

Similar to the emitter continuous contact strip 221, base continuous contact strip 222 covers an exposed or top base region of each of the NPN BJT fins 205A-205E to electrically connect base regions 212B,2112C and 212D. As will be further described below, according to an example embodiment described herein, outer or edge base regions 212A and 2112E are configured as dummy emitter regions of dummy fins 205A and 205E, respectively, and are not electrically connected by the base continuous contact strip 222 to the inner or middle BJT base regions 212B, 212C and 212D of the fin type PNP BJT structure. Because of possible fabrication process variations and stability associated with the outer edge BJT fins 205A and 205E, the dummy fins 205A and 205E are excluded from the being electrically connected to the inner BJT finger base regions 212B, 212C and 212D, thereby reducing BJT mismatch.

According to an example embodiment, the base contact strip 222 is epitaxially deposited on the base region of the BJT structure. According to another example embodiment, before the epitaxial depositing, an upper portion of the insulator material 204B, 204C and 204D is removed from between the fins, for example by etching, without any etching or removal of any of the upper portions of the fin base regions 212B, 212C and 212D, thereby reducing contact defects and process variations.

Similar to the emitter continuous contact strip 221 and base contract strip 222, collector continuous contact strip 223 covers an exposed or top collector region of each of the NPN BJT fins 205A-205E to electrically connect collector regions 213B, 213C and 213D. As will be further described below, according to an example embodiment described herein, outer or edge base regions 213A and 213E are configured as dummy emitter regions of dummy fins 205A and 205E, respectively, and are not electrically connected by the collector continuous contact strip 223 to the inner or middle BJT collector regions 213B, 213C and 213D of the fin type NPN BJT structure. Because of possible fabrication process variations and stability associated with the outer edge BJT fins 205A and 205E, the dummy fins 205A and 205E are excluded from the being electrically connected to the inner BJT finger collector regions 213B, 213C and 213D, thereby reducing BJT mismatch. According to an example embodiment, the collector contact strip 223 is epitaxially deposit ed on the collector region of the BJT structure. According to another example embodiment, before the epitaxial depositing, an upper portion of the insulator material 204B, 204C and 204D is removed from between the fins, for example by etching, without any etching or removal of any of the upper portions of the fin collector regions 213B, 213C and 213D, thereby reducing contact defects and process variations.

As described above, the emitter/base/collector contact strips 221/222/223 are epitaxially deposit ed on the respective emitter/base/collector region of the BJT structure. Before the epitaxial depositing, an upper portion of the insulator material 204 is optionally removed from between the fins, for example by etching, without any etching or removal of any of the upper portions of the fin emitter/base/collector regions 211A-211E/212A-212E/2113A-213E. This provides a large contact area (around the top and upper sidewalls of the fins), thereby reducing contact defects and process variations. According to an example embodiment, the emitter contact is deposited as a continuous emitter contact strip 221 disposed over all of the emitter regions 211B-211D of the mutually parallel fins 205B-205D of the emitter/base/collector structure; the base contact is deposited as a continuous base contact strip 222 disposed over all of the base regions 212B-212D of the mutually parallel fins 205B-20D of the emitter/base/collector structure; and the collector contact is deposited as a continuous collector contact strip 223 disposed over all of the collector regions 213B-213D of the mutually parallel fins 205B-205D of the emitter/base/collector structure. Further, according to an example embodiment, the continuous emitter contact strip 221, the continuous base contact strip 222, and the continuous collector contact strip 222 are mutually parallel; and the continuous emitter contact strip 221 is perpendicular to the fins 205A-205E of the emitter/base/collector structure; the continuous base contact strip 222 is perpendicular to the fins 205A-205E of the emitter/base/collector structure; and the continuous collector contact strip 223 is perpendicular to the fins 205A-205E of the emitter/base/collector structure.

In some embodiments, the BJT 200 may be part of an IC that also includes FINFETs. As previously mentioned for the BJT 100 of FIG. 1A, in such an embodiment there is advantageously a high degree of compatibility and overlap between fabrication of the FINFETs and the BJTs 200 of the IC, due to the BJT 200 having a FINFET architecture (i.e., being formed utilizing a set of fins/dummy fins 205A-205E analogous to fins of a FINFET).

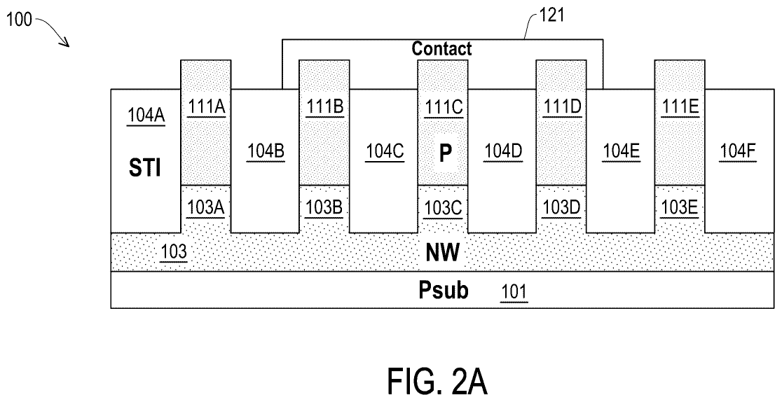

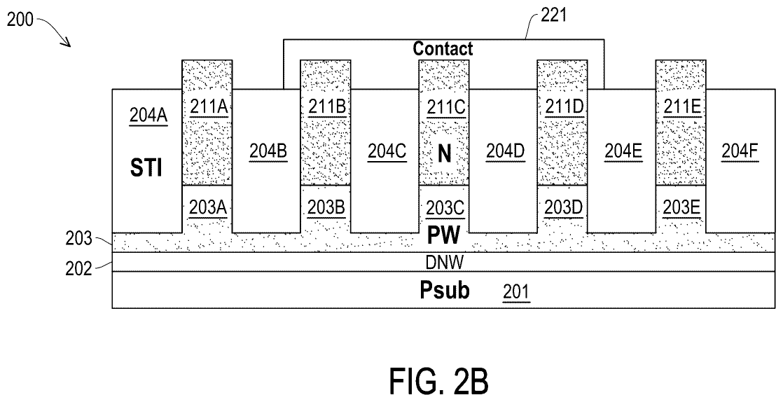

FIG. 2A is a cross sectional view of the base region of the PNP BJT structure of FIG. 1A according to an example embodiment of the present disclosure (Embodiment 1A), where like reference numbers correspond to structural elements previously described and will not be repeated here. As shown, the PNP BJT fin structure 100 includes emitter region, base region, and collector region continuous contact strips 121, 122 (not shown) and 123 (not shown), respectively, as previously described. Furthermore, unlike the PNP BJT structure 100 of FIG. 1A, this view shows that the continuous contact strips or layers 121, 122 (not shown) and 123 (not shown) may encase a top exposed portion of the emitter regions, base regions, and collector regions, whereby the contact strips effectively wrap the upper portion of the emitter/base/collector regions. This advantageously provides a large contact area (around the top and upper sidewalls of the fins), thereby reducing contact defects and process variations.

FIG. 2B is a cross sectional view of the base region of the NPN BJT structure of FIG. 1B according to an example embodiment of the present disclosure (Embodiment 1B), where like reference numbers correspond to structural elements previously described and will not be repeated here. As shown, the NPN BJT fin structure 200 includes emitter region, base region, and collector region continuous contact strips 221, 222 (not shown) and 223 (not shown), respectively, as previously described. Furthermore, unlike the NPN BJT structure 200 of FIG. 1B, this view shows that the continuous contact strips 221, 222 (not shown) and 223 (not shown) or layers may encase a top exposed portion of the emitter regions 211B, 211C and 22D, base regions (212B, 212C and 212D, not shown) and collector regions (213B, 213C and 213D, not shown), whereby the contact strips effectively wrap the upper portion of the emitter/base/collector regions. This advantageously provides a large contact area (around the top and upper sidewalls of the fins), thereby reducing contact defects and process variations.

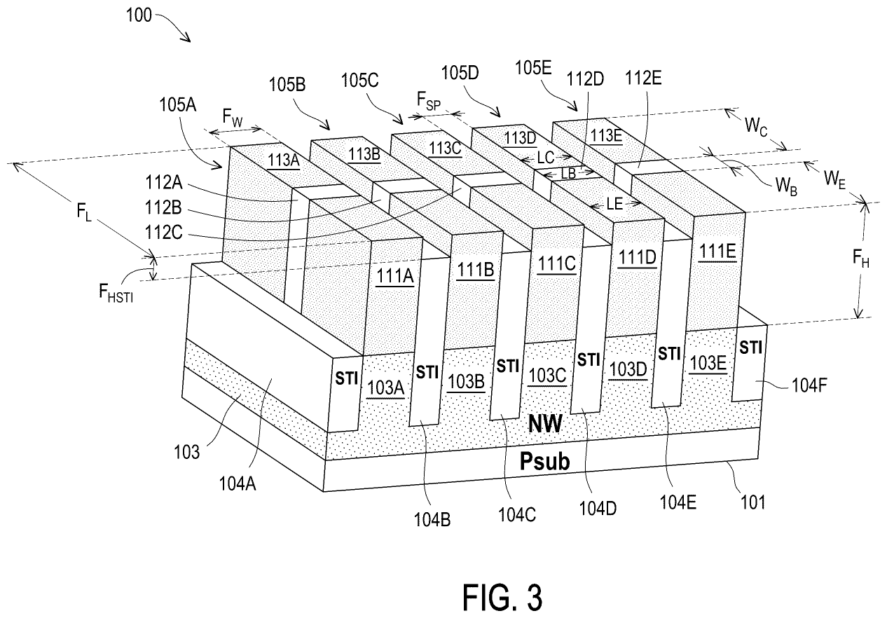

FIG. 3 is another perspective view of the PNP BJT structure according to an example embodiment of the present disclosure (Embodiment 1A), where like reference numbers correspond to structural elements previously described and will not be repeated here. FIG. 3 illustrates various dimensional details of the PNP BJT fin structure shown and described with reference to FIG. 1A. For clarity, the continuous contact strips 121, 122 and 123 are not shown. Furthermore, the dimensional details related to Fin Width (F_{W}), Fin Length (F_{L}), Emitter Width (W_{E}), Gate Length/Base Width (W_{B}), Collector Width (W_{C}), Fin Spacing/Pitch (F_{SP}), and Fin Height (F_{H}) as will be described with reference to the PNP BJT structure shown in FIG. 3, are also applicable to a NPN BJT structure as shown and described with reference to FIG. 1B.

Emitter Width (W_{E}) corresponds to the width of each of the emitter regions 111A-111E and Emitter Length (L_{E}) corresponds to the length of each of the emitter regions. Base Width (W_{B}) corresponds to the width of each of the base regions 112A-112E, also referred to as Gate Length, and Base Length (L_{B}) corresponds to the length of each of the base regions. Collector Width (W_{C}) corresponds to the width of each of the collector regions 113A-113E, and Collector Length (L_{C}) corresponds to the length of each of the collector region.

According to an example embodiment,
W_{C} (collector region width) is about 0.01 to 0.1 um;
W_{B} (base region width) is about 0.001 to 1 um;
W_{E} (emitter region width) is about 0.01 to 0.1 um;
W_{B}/W_{C} ratio s about 0.1 to 1;
W_{B}/W_{E} ratio is about 0.1 to 1; and
W_{C}/W_{E} ratio is about 1 to 10.

Fin Width (F_{W}) corresponds to the width of each of the fin BJT structures 105A-105E, Fin Length (F_{L}) corresponds to the length of each of the fins 105A-105E, and (FHSTI) corresponds to the length of an upper portion of each of the fin BJT structure 105A-105E above an upper portion or top of the STI trenches 104A-104F. Fin Height (F_{H}) corresponds to the vertical height of each of the fins 105A-105E, which is also the vertical height of each of the emitter regions 111A-111E, base regions 112A-112E and collector regions 113A-113E. Fin Spacing/Pitch (F_{SP}) corresponds to the spacing or distance between fins 105A-105E.

According to an example embodiment,
F_{W} (fin width) is about 0.001 to 0.1 um;
F_{SP} (fin spacing) is about 0.01 to 0.1 um;
F_{L} (fin length) is about 0.01 to 10 um;
F_{STI}/ F_{H} ratio is about 0.1 to 0.9; and
F_{SP}/W_{W} ratio is about 0.1 to 10.

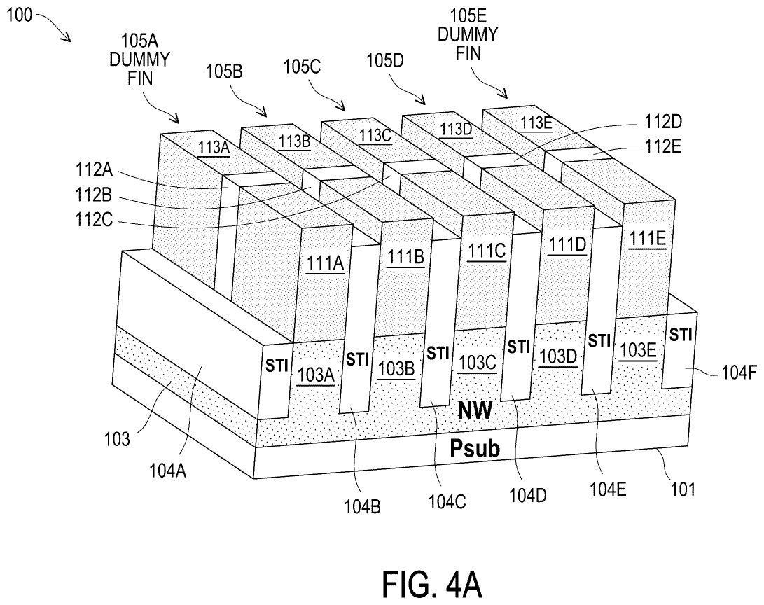

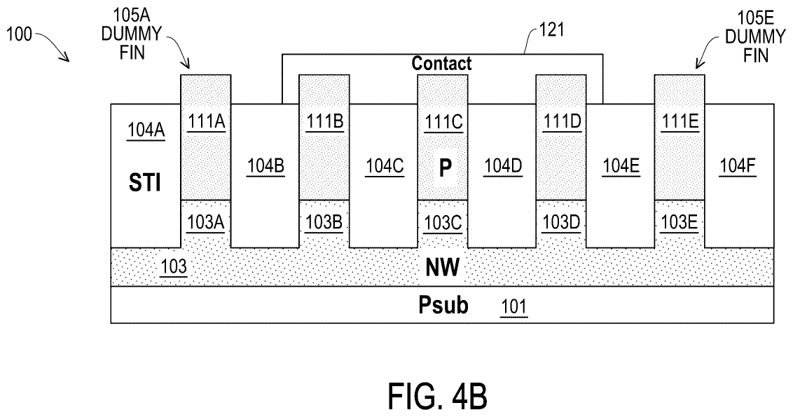

FIG. 4A is a perspective view of the PNP BJT structure of FIG. 1A including dummy fins according to an example embodiment of the present disclosure (Embodiment 1A/2A), and FIG. 4B is a cross sectional detail view of FIG. 4A, where like reference numbers correspond to structural elements previously described and will not be repeated here. For clarity, the continuous contact strips 121, 122 and 123 are not shown.

As shown, dummy fins 105A and 105E are located at the outer periphery of the PNP BJT structure 100. As previously described with reference to FIG. 1A, the dummy fins 105A and 105E are not electrically connected to the inner or middle fins 105B, 105C and 105D, or any of the corresponding emitter, base, and collector regions, of the fin type PNP BJT structure 100. Because of possible fabrication process variations and stability associated with the outer edge BJT fins 105A and 105E, the dummy fins 105A and 105E are excluded from the being electrically connected to the inner BJT finger base regions 112B, 112C and 112D, as well as emitter regions 111B, 111C and 111D, and collector regions 113B, 113C and 113D, thereby reducing BJT mismatch.

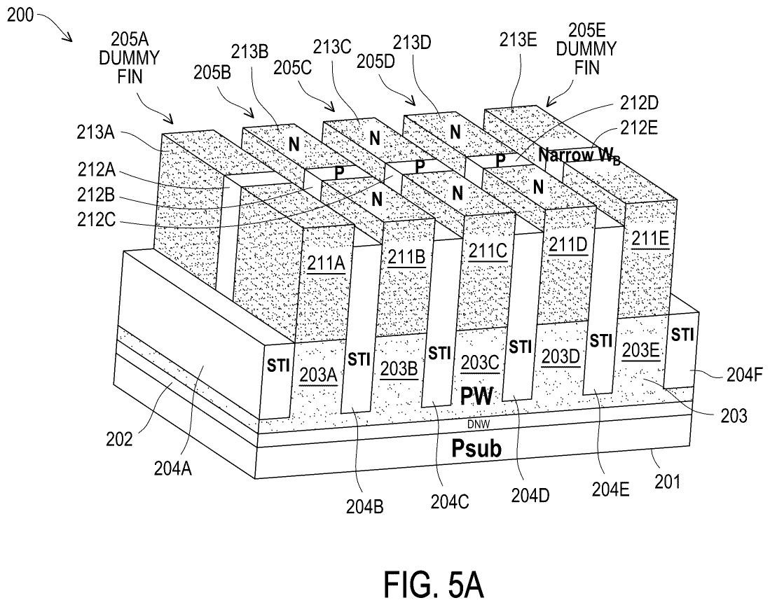

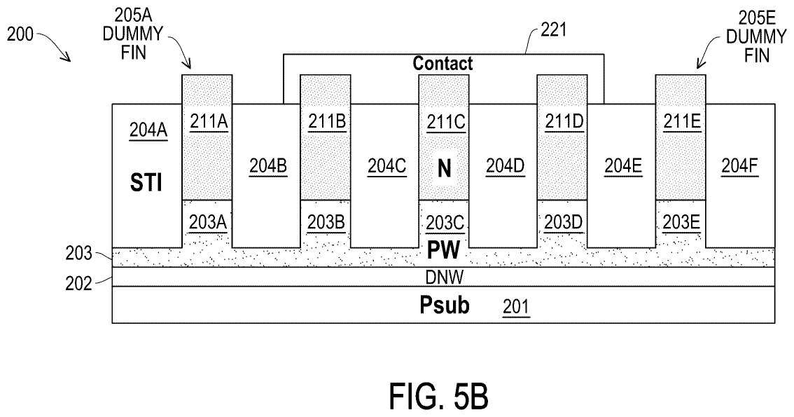

FIG. 5A is a perspective view of the NPN BJT structure of FIG. 1B including dummy fins according to another example embodiment of the present disclosure (Embodiment 1B/2B) and FIG. 5B is a cross sectional detail view of FIG. 5A, where like reference numbers correspond to structural elements previously described and will not be repeated here. For clarity, the continuous contact strips 221, 222 and 223 are not shown.

As shown, dummy fins 205A and 205E are located at the outer periphery of the NPN BJT structure 200. As previously described with reference to FIG. 1B, the dummy fins 205A and 205E are not electrically connected to the inner or middle fins 205B, 205C and 205D, or any of the corresponding emitter, base, and collector regions, of the fin type PNP BJT structure 200. Because of possible fabrication process variations and stability associated with the outer edge BJT fins 205A and 205E, the dummy fins 205A and 205E are excluded from the being electrically connected to the inner BJT finger base regions 212B, 212C and 212D, as well as emitter regions 211B, x211C and 211D, and collector regions 213B, 213C and 213D, thereby reducing BJT mismatch.

In the foregoing embodiments, there is one dummy fin on each side of the active BJT fins. However, it is contemplated to have two (or more) dummy fins on each side of the active BJT fins. Such a design may further improve robustness against process variations and further improve BJT stability.

In the foregoing embodiments, the BJT structure implements a single BJT. In some applications, it may be desirable for the BJT structure to implement multiple BJTs. For example, a structure that implements two BJTs with a common collector has use in certain types of circuits. As disclosed in the following, the fin-type BJT structures can be modified to implement such a BJT pair with common collector in a unitary structure.

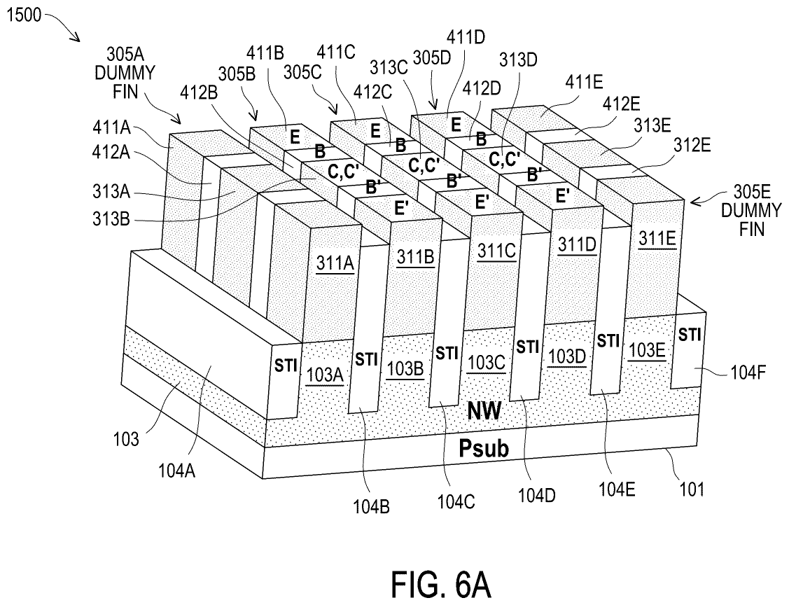

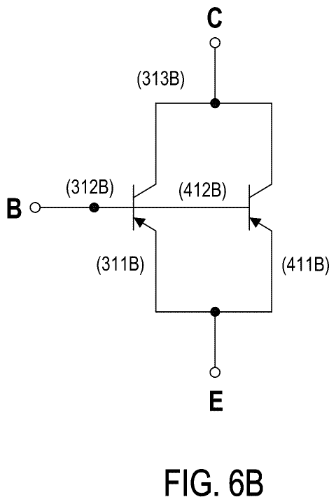

With reference to FIG. 6A, illustrated is a fin type PNP BJT structure wherein each fin includes multiple (illustrative two) BJTs according to an example embodiment of the present disclosure, where like reference numbers correspond to structural elements previously described and will not be repeated here. For clarity, continuous contact strips 321, 322, 323, 324, and 325 are not shown but are described. FIG. 6B shows an equivalent circuit of the parallel fin type PNP BJT structure of FIG. 6A, including BJT fin 305B common collector 313B configuration.

The multiple PNP BJT structure shown can be considered a parallel PNP BJT structure, whereby multiple base regions and emitter regions are included in each fin structure to increase the size of each fin PNP BJT structure. The multiple/parallel PNP BJT structure 1500 includes a P-type semiconductor substrate 101, an N-type well (NW) 103 formed on the P-type semiconductor substrate 101 to create an isolation region, optionally including multiple fingers or buried NW fins 103A-103E, which isolate PNP BJT fins 305A-305E from the substrate 101. Example materials of the substrate 101 include Silicon (Si), Germanium (Ge) Gallium Arsenide (GaAs), or another semiconductor material. The illustrative examples employ a silicon substrate 101. As shown, each of the NW fingers 103A-103E and PNP BJT fins 305A-305E are isolated from each other with isolation regions 104A-104F, which can be formed with known shallow trench isolation (STI) fabrication processes, and the like, such as local oxidation of silicon to form silicon dioxide area (LOCOS) fabrication processes and deep trench isolation (DTI) fabrication processes.

Each of the PNP BJT fins 305A-305E is doped to form a first P doped emitter region (311A-311E, respectively), a first N doped base region (312A-312E), respectively, a P doped collector region (313A-313E, respectively) which provides a common collector region for each BJT, a second N doped base region (412A-412E), and a second P doped emitter region (411A-411E, respectively). The doping can suitably employ ion implantation. Example P type implant dopants include Boron (B), Boron Fluoride (BF2), In and Carbon (C), with a constant and/or gradient doping profile. Example N type implant dopants include N, P, As, Sb and C. The doping concentrations in some embodiments include an Emitter dopant concentration>Base dopant concentration>Collector dopant concentration.

In other words, provided and shown in FIG. 6A is a fin type PNP BJT structure including mutually parallel fins 305A-305E with an insulator material 104A-104E disposed between the fins 305A-305E, the mutually parallel fins 305A-305E having regions of alternating first and second doping types along the fins, the regions including at least one emitter region of the first doping type, at least one base region of the second doping type, and at least one collector region of the first doping type.

A first emitter continuous contact strip 321 (not shown, but analogous to the emitter continuous contact strip 121 of the embodiment of FIG. 1A) covers an exposed or top emitter region of each of the PNP BJT fins 305A-305E to electrically connect emitter regions 311B, 311C and 311D, the first emitter continuous contact strip 321 (not shown) identical in structure to the continuous contact strip 121 previously described and shown in FIG. 1A. Outer or edge emitter regions 311A and 311E are configured as dummy emitter regions of dummy fins 305A and 305E, respectively, and are not electrically connected to the inner or middle BJT emitter regions 311B, 311C and 311D of the fin type PNP BJT structure.

A first base continuous contact strip 322 (not shown, but analogous to the base continuous contact strip 122 of the embodiment of FIG. 1A) covers an exposed or top base region of each of the PNP BJT fins 305A-305E to electrically connect base regions 312B, 312C and 312D, the first base continuous contact strip 321 (not shown) identical in structure to the continuous contact strip 122 previously described and shown in FIG. 1A. Outer or edge base regions 312A and 312E are configured as dummy emitter regions of dummy fins 305A and 305E, respectively, and are not electrically connected to the inner or middle BJT base regions 312B, 312C and 312D of the fin type PNP BJT structure. Because of possible fabrication process variations and stability associated with the outer edge BJT fins 305A and 305E, the dummy fins 305A and 305E are excluded from the being electrically connected to the inner BJT finger base regions 312B, 312C and 312D, thereby reducing BJT mismatch.

A common collector continuous contact strip 323 (not shown, but analogous to the collector continuous contact strip 123 of the embodiment of FIG. 1A) covers an exposed or top collector region of each of the PNP BJT fins 305A-305E to electrically connect collector regions 313B, 313C and 313D, the common collector continuous contact strip 323 (not shown) identical in structure to the continuous contact strip 123 previously described and shown in FIG. 1A. Outer or edge collector regions 313A and 313E are configured as dummy collector regions of dummy fins 305A and 305E, respectively, and are not electrically connected to the inner or middle BJT collector regions 313B, 313C and 313D of the fin type PNP BJT structure. Because of possible fabrication process variations and stability associated with the outer edge BJT fins 305A and 305E, the dummy fins 305A and 305E are excluded from the being electrically connected to the inner BJT finger collector regions 313B, 313C and 313D, thereby reducing BJT mismatch.

A second base continuous contact strip 324 (not shown, but analogous to the base continuous contact strip 122 of the embodiment of FIG. 1A) covers an exposed or top base region of each of the PNP BJT fins 305A-305E to electrically connect base regions 412B, 412C and 412D. The second continuous base contact strip 324 (not shown) is similar in structure to the continuous contact strip 122 previously described and shown in FIG. 1A. Outer or edge base regions 412A and 412E are configured as dummy emitter regions of dummy fins 305A and 305E, respectively, and are not electrically connected to the inner or middle BJT base regions 412B, 412C and 412D of the fin type PNP BJT structure.

A second emitter continuous contact strip 325 (not shown, but analogous to the emitter continuous contact strip 121 of the embodiment of FIG. 1A) covers an exposed or top emitter region of each of the PNP BJT fins 305A-305E to electrically connect emitter regions 411B, 411C and 411D, the second emitter continuous contact strip 325 (not shown) identical in structure to the continuous contact strip 121 previously described and shown in FIG. 1A. Outer or edge emitter regions 411A and 411E are configured as dummy emitter regions of dummy fins 305A and 305E, respectively, and are not electrically connected to the inner or middle BJT emitter regions 411B, 411C and 411D of the fin type PNP BJT structure.

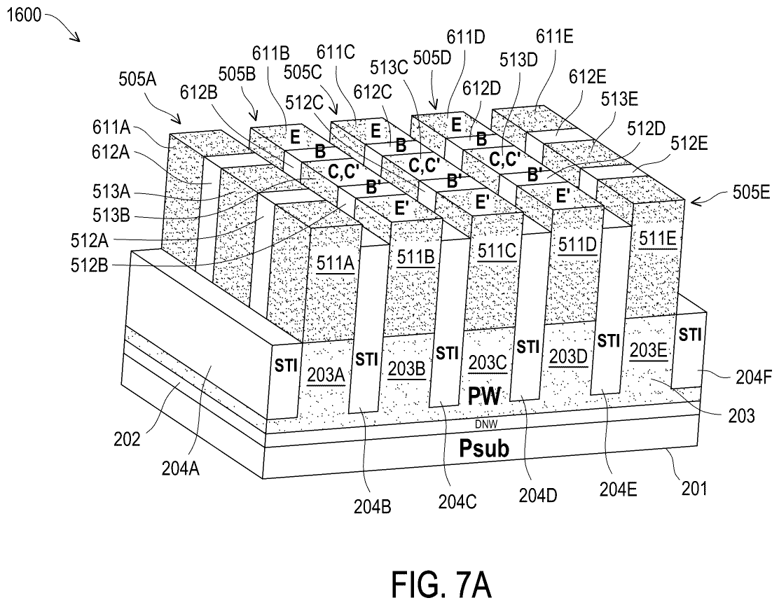

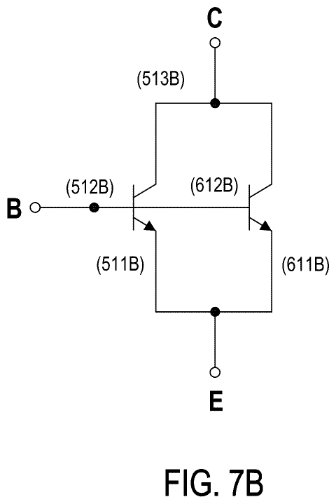

With reference to FIG. 7A, illustrated is a fin type NPN BJT structure wherein each fin includes multiple (illustrative two) BJTs according to an example embodiment of the present disclosure, where like reference numbers correspond to structural elements previously described and will not be repeated here. For clarity, continuous contact strips 521, 522, 523, 524, and 525 are not shown but are described. FIG. 7B shows an equivalent circuit of the parallel fin type NPN BJT structure of FIG. 7A, including BJT fin 505B including a common collector 513B configuration.

The multiple NPN BJT structure shown can be considered a parallel NPN BJT structure, whereby multiple base regions and emitter regions are included in each fin structure to increase the size of each fin NPN BJT structure. The multiple/parallel NPN BJT structure 1600 includes a P-type semiconductor substrate 201, a DNW 202, an N-type well (NW) 203 formed on the P-type semiconductor substrate 201 to create an isolation region, optionally including multiple fingers or buried NW fins 203A-203E, which isolate NPN BJT fins 505A-505E from the substrate 201. Example materials of the substrate 201 include Silicon (Si), Germanium (Ge) Gallium Arsenide (GaAs), or another semiconductor material. The illustrative examples employ a silicon substrate 201. As shown, each of the NW fingers 203A-203E and PNP BJT fins 505A-505E are isolated from each other with isolation region 204, including isolation region fingers 204A-204F, which can be formed with shallow trench isolation (STI) fabrication processes, and the like, such as local oxidation of silicon to form silicon dioxide area (LOCOS) fabrication processes and deep trench isolation (DTI) fabrication processes.

Each of the NPN BJT fins 505A-505E is doped to form a first N doped emitter region (511A-511E, respectively), a first P doped base region (512A-512E), respectively, a N doped collector region (513A-513E, respectively) which provides a common collector region for each BJT, a second P doped base region (612A-612E), and a second N doped emitter region (611A-611E, respectively). The doping can suitably employ ion implantation. Example P type implant dopants include Boron (B), Boron Fluoride (BF2), In and Carbon (C), with a constant and/or gradient doping profile. Example N type implant dopants include N, P, As, Sb and C. The doping concentrations in some embodiments include an Emitter dopant concentration>Base dopant concentration>Collector dopant concentration.

In other words, provided and shown in FIG. 7A is a fin type NPN BJT structure including mutually parallel fins 505A-505E with an insulator material 204A-204E disposed between the fins 505A-505E, the mutually parallel fins 505A-505E having regions of alternating first and second doping types along the fins, the regions including at least one emitter region of the first doping type, at least one base region of the second doping type, and at least one collector region of the first doping type.

A first emitter continuous contact strip 521 (not shown, but analogous to the emitter continuous contact strip 221 of the embodiment of FIG. 1B) covers an exposed or top emitter region of each of the NPN BJT fins 505A-505E to electrically connect emitter regions 511B, 511C and 5311D, the first emitter continuous contact strip 521 (not shown) identical in structure to the continuous contact strip 221 previously described and shown in FIG. 1B. Outer or edge emitter regions 511A and 511E are configured as dummy emitter regions of dummy fins 505A and 505E, respectively, and are not electrically connected to the inner or middle BJT emitter regions 511B, 511C and 511D of the fin type NPN BJT structure.

A first base continuous contact strip 522 (not shown, but analogous to the base continuous contact strip 222 of the embodiment of FIG. 1B) covers an exposed or top base region of each of the NPN BJT fins 505A-505E to electrically connect base regions 512B, 512C and 512D, the first base continuous contact strip 521 (not shown) identical in structure to the continuous contact strip 222 previously described and shown in FIG. 1B. Outer or edge base regions 512A and 512E are configured as dummy emitter regions of dummy fins 505A and 505E, respectively, and are not electrically connected to the inner or middle BJT base regions 512B, 512C and 512D of the fin type NPN BJT structure. Because of possible fabrication process variations and stability associated with the outer edge BJT fins 505A and 505E, the dummy fins 505A and 505E are excluded from the being electrically connected to the inner BJT finger base regions 512B, 512C and 512D, thereby reducing BJT mismatch.

A common collector continuous contact strip 523 (not shown, but analogous to the collector continuous contact strip 223 of the embodiment of FIG. 1B) covers an exposed or top collector region of each of the NPN BJT fins 505A-505E to electrically connect collector regions 513B, 513C and 513D, the common collector continuous contact strip 523 (not shown) identical in structure to the continuous contact strip 223 previously described and shown in FIG. 1B. Outer or edge collector regions 513A and 513E are configured as dummy collector regions of dummy fins 505A and 505E, respectively, and are not electrically connected to the inner or middle BJT collector regions 513B, 513C and 513D of the fin type NPN BJT structure. Because of possible fabrication process variations and stability associated with the outer edge BJT fins 505A and 505E, the dummy fins 505A and 505E are excluded from the being electrically connected to the inner BJT finger collector regions 513B, 513C and 513D, thereby reducing BJT mismatch.

A second base continuous contact strip 524 (not shown, but analogous to the base continuous contact strip 222 of the embodiment of FIG. 1B) covers an exposed or top base region of each of the NPN BJT fins 505A-505E to electrically connect base regions 612B, 612C and 612D. The second continuous base contact strip 524 (not shown) is similar in structure to the continuous contact strip 222 previously described and shown in FIG. 1B. Outer or edge base regions 612A and 612E are configured as dummy emitter regions of dummy fins 505A and 505E, respectively, and are not electrically connected to the inner or middle BJT base regions 612B, 612C and 612D of the fin type NPN BJT structure.

A second emitter continuous contact strip 525 (not shown, but analogous to the emitter continuous contact strip 221 of the embodiment of FIG. 1B) covers an exposed or top emitter region of each of the NPN BJT fins 505A-505E to electrically connect emitter regions 611B, 611C and 611D, the second emitter continuous contact strip 525 (not shown) identical in structure to the continuous contact strip 221 previously described and shown in FIG. 1B. Outer or edge emitter regions 611A and 611E are configured as dummy emitter regions of dummy fins 505A and 505E, respectively, and are not electrically connected to the inner or middle BJT emitter regions 511B, 511C and 511D of the fin type NPN BJT structure.

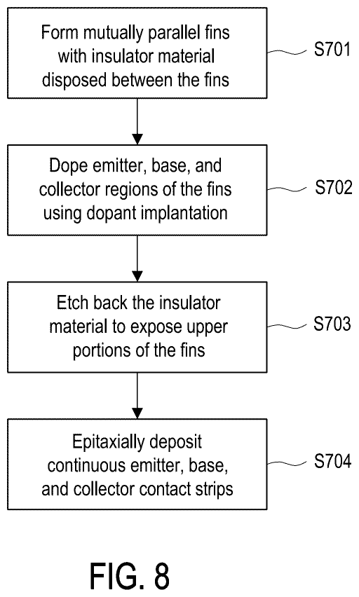

With reference to FIG. 8, illustrated are various process steps of forming a fin type BJT structure according to example embodiments of the present disclosure.
At step S701, mutually parallel fins are formed with an insulator material disposed between the fins. The step S701 can be performed using processing analogous to that used to form the fins of a FINFET transistor.
At step S702, emitter, base, and collector regions of the fins are doped using dopant implantation processes. According to an example embodiment, the emitter dopant concentration is greater than the base dopant concentration, and the base dopant concentration is greater than the collector dopant concentration. The dopant profiles for each the emitter, base, and collector can be a constant dopant profile, or a gradient dopant profile.
At step S703, the insulator material is etched back to expose upper portions of the fins. According to an example embodiment, the etching process does not remove any upper portion of the fins. For an example embodiment in which the fins are silicon fins and the insulator material is silicon dioxide, the etching suitably employs a wet or dry etchant with high selectivity for etching silicon dioxide over silicon, such as a hydrofluoric acid-based wet etchant or a fluorine-or chlorine-based dry etchant,
At step S704, continuous emitter, base, and collector contact strips are epitaxially deposited on the upper portions of the fins. This suitably entails disposing and patterning a photoresist to form openings corresponding to the areas of the intended continuous strips, and epitaxially depositing the silicon or other material forming the continuous contact strips.

Based on the above discussions, it can be seen that the present disclosure offers advantages. It is understood, however, that other embodiments may offer additional advantages, and not all advantages are necessarily disclosed herein, and that no particular advantage is required for all embodiments. One advantage is that the disclosed fin type PNP/NPN BJT structures provide an improved Gain/Beta by providing a relatively narrower base region width, i.e., gate length.

In the following, some further embodiments are described.

In a nonlimiting illustrative embodiment, a method of forming a bipolar junction transistor (BJT) structure, the method comprising: providing an emitter/base/collector structure comprising mutually parallel fins with an insulator material disposed between the fins, each fin of the emitter/base/collector structure having first and second peripheral regions doped with a first doping type on opposite sides of a central region doped with a second doping type opposite the first doping type, wherein the first peripheral regions of the fins are an emitter of the BJT structure, the central regions of the fins are a base of the BJT structure, and the second peripheral regions of the fins are a collector of the BJT structure; and epitaxially depositing an emitter contact on the emitter of the BJT structure, a base contact on the base of the BJT structure, and a collector contact on the collector of the BJT structure.

In another nonlimiting illustrative embodiment, a bipolar junction transistor (BJT) comprising: mutually parallel fins with an insulator material disposed between the fins, the mutually parallel fins having regions of alternating first and second doping types along the fins, the regions including at least one emitter region of the first doping type, at least one base region of the second doping type, and at least one collector region of the first doping type; at least one continuous emitter contact strip oriented perpendicular to the mutually parallel fins and disposed over a corresponding emitter region of the first doping type; at least one continuous base contact strip oriented perpendicular to the mutually parallel fins and disposed over a corresponding base region of the second doping type; and at least one continuous collector contact strip oriented perpendicular to the mutually parallel fins and disposed over a corresponding collector region of the first doping type.

In another nonlimiting illustrative embodiment, a method of forming a bipolar junction transistor (BJT) structure, the method comprising: providing an emitter/base/collector structure comprising mutually parallel fins with an insulator material disposed between the fins, the mutually parallel fins having regions of alternating first and second doping types along the fins, the regions including at least one emitter region of the first doping type, at least one base region of the second doping type, and at least one collector region of the first doping type; and epitaxially depositing emitter contacts on the emitter regions, base contacts on the base regions, and collector contacts on the collector of the BJT structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a bipolar junction transistor (BJT) structure, the method comprising:
providing an emitter/base/collector structure comprising mutually parallel fins with an insulator material disposed between the fins, each fin of the emitter/base/collector structure having first and second peripheral regions doped with a first doping type on opposite sides of a central region doped with a second doping type opposite the first doping type, wherein the first peripheral regions of the fins are an emitter of the BJT structure, the central regions of the fins are a base of the BJT structure, and the second peripheral regions of the fins are a collector of the BJT structure; and
epitaxially depositing an emitter contact on the emitter of the BJT structure, a base contact on the base of the BJT structure, and a collector contact on the collector of the BJT structure.

2. The method of claim 1, further comprising:
after the providing and before the epitaxial depositing, removing an upper portion of the insulator material from between the fins.

3. The method of claim 2, wherein the removing of the upper portion of the insulator material from between the fins does not remove an upper portion of the fins.

4. The method of claim 2, wherein:
the emitter contact is deposited as a continuous emitter contact strip disposed over all of the first peripheral regions of the mutually parallel fins of the emitter/base/collector structure;
the base contact is deposited as a continuous base contact strip disposed over all of the central regions of the mutually parallel fins of the emitter/base/collector structure; and
the collector contact is deposited as a continuous collector contact strip disposed over all of the second peripheral regions of the mutually parallel fins of the emitter/base/collector structure.

5. The method of claim 4, wherein:
the continuous emitter contact strip, the continuous base contact strip, and the continuous collector contact strip are mutually parallel;
the continuous emitter contact strip is perpendicular to the fins of the emitter/base/collector structure;
the continuous base contact strip is perpendicular to the fins of the emitter/base/collector structure; and
the continuous collector contact strip is perpendicular to the fins of the emitter/base/collector structure.

6. The method of claim 1, wherein the emitter of the BJT structure has a higher doping than the collector of the BJT structure.

7. The method of claim 1, wherein:
the first doping type is p-type and the second doping type is n-type; or
the first doping type is n-type and the second doping type is p-type.

8. The method of claim 1, wherein the providing of the emitter/base/collector structure further includes providing dummy fins that are mutually parallel with the fins of the emitter/base/collector structure and are disposed on opposite sides of the emitter/base/collector structure, the emitter, base, and collector contacts not being disposed on the dummy fins.

9. The method of claim 1, wherein the providing of the emitter/base/collector structure includes:
performing dopant implantation to dope the first peripheral region with the first doping type, to dope the second peripheral region with the first doping type, and to dope the central region with the second doping type.

10. A bipolar junction transistor (BJT) comprising:
mutually parallel fins with an insulator material disposed between the fins, the mutually parallel fins having regions of alternating first and second doping types along the fins, the regions including at least one emitter region of the first doping type, at least one base region of the second doping type, and at least one collector region of the first doping type;
at least one continuous emitter contact strip oriented perpendicular to the mutually parallel fins and disposed over a corresponding emitter region of the first doping type;
at least one continuous base contact strip oriented perpendicular to the mutually parallel fins and disposed over a corresponding base region of the second doping type; and
at least one continuous collector contact strip oriented perpendicular to the mutually parallel fins and disposed over a corresponding collector region of the first doping type.

11. The BJT of claim 10, wherein the regions of alternating first and second doping types along the fins include three regions of alternating first and second doping types along the fins, consisting of:
a peripheral emitter region of the first doping type;
a peripheral collector region of the first doping type; and
a central base region of the second doping type disposed between the peripheral emitter region and the peripheral collector region.

12. The BJT of claim 10, wherein the regions of alternating first and second doping types along the fins include five regions of alternating first and second doping types along the fins, consisting of:
a first peripheral emitter region of the first doping type;
a second peripheral emitter region of the first doping type;
a common collector region of the first doping type;
a first base region of the second doping type disposed between the first peripheral emitter region and the common collector region; and
a second base region of the second doping type disposed between the second peripheral emitter region and the common collector region.

13. The BJT of claim 10, wherein upper portions of the mutually parallel fins extend above the insulator material disposed between the fins.

14. The BJT of claim 10, further comprising:
first and second dummy fins that are mutually parallel with the mutually parallel fins and that are disposed on opposite sides of the mutually parallel fins.

15. A method of forming a bipolar junction transistor (BJT) structure, the method comprising:
providing an emitter/base/collector structure comprising mutually parallel fins with an insulator material disposed between the fins, the mutually parallel fins having regions of alternating first and second doping types along the fins, the regions including at least one emitter region of the first doping type, at least one base region of the second doping type, and at least one collector region of the first doping type; and
epitaxially depositing emitter contacts on the emitter regions, base contacts on the base regions, and collector contacts on the collector of the BJT structure.

16. The method of claim 15, further comprising:
after the providing and before the epitaxial depositing, removing an upper portion of the insulator material from between the fins.

17. The method of claim 16, wherein the removing of the upper portion of the insulator material from between the fins does not remove an upper portion of the fins.

18. The method of claim 15, wherein:
the emitter contact is deposited as a continuous emitter contact strip disposed over a single emitter region of each of the mutually parallel fins of the emitter/base/collector structure;
the base contact is deposited as a continuous base contact strip disposed over a single base region of each of the mutually parallel fins of the emitter/base/collector structure; and
the collector contact is deposited as a continuous collector contact strip disposed over a single collector region of each of the mutually parallel fins of the emitter/base/collector structure.

19. The method of claim 18, wherein the regions of alternating first and second doping types along the fins include five regions of alternating first and second doping types along the fins, consisting of:
a first peripheral emitter region of the first doping type;
a second peripheral emitter region of the first doping type;
a common collector region of the first doping type;
a first base region of the second doping type disposed between the first peripheral emitter region and the common collector region; and
a second base region of the second doping type disposed between the second peripheral emitter region and the common collector region.

20. The method of claim 15, wherein upper portions of the mutually parallel fins extend above the insulator material disposed between the fins, and at least one of the emitter contacts, base contacts or collector contacts cover at least a portion of three sides of upper portions of the respective emitter regions, base regions and collector regions.
